(19) United States
(12) Patent Application Publication
(10) Pub. No.: US 2010/0025100 A1
(43) Pub. Date: Feb. 4, 2010

(54) ELECTRICALLY CONDUCTIVE POLYMERIC ELASTOMER COMPOSITION AND ELECTROMAGNETIC WAVE SHIELD COMPRISING THE COMPOSITION

(76) Inventors: Shokichi Hamano, Saitama (JP); Tomonori Sato, Gunma (JP); Shiro Tanami, Gunma (JP)

Correspondence Address: SHLESINGER, ARKWRIGHT & GARVEY LLP, 5845 Richmond Highway, Suite 415, ALEXANDRIA, VA, 22303, US

(21) Appl. No.: 12/449,661

(22) PCT Filed: Mar. 4, 2008
(86) PCT No.: PCT/JP2008/000436

§ 371 Date: Aug. 20, 2009

(30) Foreign Application Priority Data
Mar. 5, 2007 (JP) 2007-054746

(51) Int. Cl. H05K 9/00; H01B 1/22

(52) U.S. Cl. 174/388; 252/512; 252/513; 252/514

(57) ABSTRACT

Provided is a transparent complex conductive polymer elastomer composition that maintains electromagnetic-wave shielding performance and that has a favorable light transmittance. The composition is a transparent elastomer provided in the immediate vicinity of a viewer's side of a display unit, the transparent elastomer being composed of a conductive particle complex and a non-conductive organic polymer 13, the conductive particle complex being composed of a large number of conductive metal particles 11 and a conductive organic polymer 12 that covers the metal particles 11 and that cross-links the large number of conductive metal particles to form a three-dimensional mesh structure, and the non-conductive organic polymer 13 serving as a binder for maintaining the three-dimensional structure of the conductive particle complex.

### TECHNICAL FIELD

The present invention relates to a conductive polymer elastomer composition and an electromagnetic-wave shield composed of the same.

More specifically, the present invention relates to a conductive polymer elastomer composition and to an electromagnetic-wave shield that acts as a shield against electromagnetic waves generated from various electronic devices and that thereby prevents leakage of the electromagnetic waves to the outside, or that includes the conductive polymer elastomer composition and that is provided in the immediate vicinity of a display unit, between the display unit and a viewer, so that internal electronic devices are protected from electromagnetic waves from the outside.

### BACKGROUND ART

As electromagnetic-wave shielding methods for protecting electronic devices from electromagnetic interference and thereby preventing improper operation or the like, methods are known in which a conductive coating is applied to the inner surface of a housing or in which a conductive film is formed by metal spraying, vacuum vapor deposition, or the like.

Furthermore, high light transmissivity is a necessary condition for use between a display unit and a viewer.

Electromagnetic noise interference is increasing in accordance with the sophistication of functions and increased use of electric and electronic devices, and electromagnetic waves are generated from display units (also referred to as displays), such as CRT displays or plasma display panels (referred to as PDPs).

A PDP is an assembly of a glass substrate having electrodes and a phosphor layer thereon and a glass substrate having transparent electrodes thereon, and a high level of electromagnetic waves, near infrared rays, and heat are generated during its operation. Usually, for the purpose of shielding against electromagnetic waves, a front panel including an electromagnetic-wave shield sheet is provided on the front surface of the PDP. Regarding the function of shielding against electromagnetic waves generated from the front surface of the display, not less than 30 dB at 30 MHz to 1 GHz is necessary.

Furthermore, there is also a need for shielding against near infrared rays generated from the front surface of the display and having a wavelength of 800 to 1,100 nm, which cause improper operation of other devices, such as a VTR.

Furthermore, for the purpose of improving viewability of images displayed on the display, the electromagnetic-wave shield portion should be hardly viewable, and the display as a whole should have an appropriate level of transparency (visible light transmissivity or visible light transmittance).

Furthermore, since a feature of PDPs is large screens, and electromagnetic-wave shield sheets have sizes (outer dimensions), for example, of 621×831 mm for 37-inch, 983×583 mm for 42-inch, and even larger sizes are available, there exists a demand for development of a conductive polymer elastomer composition that can readily be handled during manufacturing.

Accordingly, regarding electromagnetic-wave shield sheets, the ability to shield against electromagnetic waves and near infrared rays, an inconspicuous electromagnetic-wave shield material, and favorable viewability with an appropriate level of transparency are needed. Furthermore, there has been a demand for such an electromagnetic-wave shield sheet in which warping or unwanted introduction of air bubbles rarely occurs in the manufacturing process and whose productivity is high, with a small number of manufacturing steps achieved by, e.g., performing “blackening” (black-shadowing for emphasizing other colors), which is often needed for display materials, simultaneously with plating.

For achieving light transmissivity and shielding performance simultaneously, there is a known example formed of a transparent substrate and a mesh-shaped conductive layer pattern formed thereon.

As methods of manufacturing an electromagnetic-wave shield sheet having a mesh-shaped metal layer, usually, the following three methods are used.

(1) A method is known in which conductive ink is printed on a transparent base by gravure offset printing to form a pattern, and metal plating is applied on the conductive ink layer (e.g., see Patent Documents 1 and 2).

(2) A method is known in which conductive ink or photosensitive coating liquid containing chemical plating catalyst is applied over the entire surface of a transparent base, the coating layer is formed into a mesh by photolithography, and then metal plating is applied on the mesh.

(3) A method is known in which a transparent base and a metal foil are laminated using a bonding agent composed of a thermosetting resin, and then the metal foil is formed into a mesh by photolithography (e.g., see Patent Documents 3 and 4).

Related art documentation regarding the present invention includes the following:

### Patent Document 1: Japanese Unexamined Patent Application, Publication No. 2000-13088

### Patent Document 2: Japanese Unexamined Patent Application, Publication No. 2000-59079

Patent Document 3: Japanese Unexamined Patent Application, Publication No. H11-145678

### Patent Document 4: Japanese Unexamined Patent Application, Publication No.

### DISCLOSURE OF THE INVENTION

### Problem to be Solved by the Invention

The above-described methods based on application of a conductive coating, however, suffer from the problem that the metal particles used in the conductive coating are easily oxidized so that the electromagnetic-wave shielding performance becomes degraded.

Furthermore, in the above-described conductive coating applied to the inner surface of the housing, a large amount of metal powder is added in order to reduce resistance. This results in the problem of low light transmissivity.

A disadvantage with the above method (1) of manufacturing an electromagnetic-wave shield sheet having a mesh-shaped metal layer is that thinning of the printed pattern is difficult and the precision is poor, the mesh formed by applying another metal plating on the pattern has a poor external appearance, and the viewability of displayed images is unsatisfactory. Thus, it is not practical to use the sheet as an electromagnetic-wave shield sheet for a high-definition display.

Furthermore, a disadvantage with the above method (2) is that it is not possible to blacken the metal layer on the side of the transparent base surface. Furthermore, in the manufacturing process, plating takes a long time with conductive ink since the electrical resistance of the conductive ink is high. This results in the problem of low productivity.

Furthermore, a disadvantage with the above method (3) is that, since different materials are laminated, warping or deformation of the lamination occurs due to distortion that occurs in an aging process for promoting curing of the bonding agent after lamination, the transparency of the opening portions of the mesh is poor due to diffuse reflection caused by projections and recesses formed by transfer of the roughness of the metal foil onto the surface of the bonding agent exposed to the mesh opening portions, and the metal mesh itself has a poor external appearance due to nonuniformity of the surface of the electrolyte copper foil used.

Furthermore, in the manufacturing process, due to the lamination formed by using the thermosetting-resin bonding agent, the transparency is reduced by uneven application of the bonding agent or unwanted formation of creases or introduction of air bubbles, and furthermore, it becomes necessary to add a transparentizing step for achieving transparency by burying the rough surface of the bonding agent at the mesh opening portions, and also to add a blackening step of blackening the metal mesh portion, which results in the problem of reduced productivity.

The present invention has been made in view of the points described above, and it is an object thereof to provide a conductive polymer elastomer composition that can be suitably used as an electromagnetic-wave shield material having a favorable light transmissivity and electromagnetic-wave shielding performance, or the like.

### Means for Solving the Problems

The inventors have conceived the present invention as a result of intensive research for achieving the above object. Specifically, the present invention relates to a conductive particle complex in which conductive metal particles are covered with a conductive organic polymer, a conductive polymer elastomer composition composed of the conductive particle complex and a non-conductive organic polymer serving as a binder, and an electromagnetic-wave shield, and the inventors have discovered that an electromagnetic-wave shielding effect can be achieved by forming the conductive particle complex in a three-dimensional mesh structure and maintaining the structure stable.

A conductive polymer elastomer composition according to the present invention is a transparent elastomer provided in the immediate vicinity of a viewer's side of a display unit, wherein the conductive polymer elastomer composition includes conductive and non-conductive organic polymers and conductive metal particles, the organic polymers having a non-conductive acrylic polymer as a binder and a three-dimensional mesh structure formed of a conjugated conductive organic polymer including a double bond in its repeating unit (As an aspect 1). Specifically, as shown in FIG. 1, the conductive polymer elastomer composition is composed of a conductive particle complex and a non-conductive organic polymer 13, the conductive particle complex being composed of a large number of conductive metal particles 11 and a conductive organic polymer 12 that covers the metal particles 11 and that cross-links the large number of conductive metal particles to form a three-dimensional mesh structure, and the non-conductive organic polymer 13 serving as a binder for maintaining the three-dimensional structure of the conductive particle complex. Furthermore, preferably, the volume specific resistance value (SRIS 2301) is not more than 0.1 Ω·cm, the light transmittance measured by a spectrophotometer is not less than 80%, and the hardness is not more than 80 in terms of Asuka C. Furthermore, anti-corrosion is not more than 30% in terms of change in resistance, and preferably not more than 10%.

Preferably, the conductive organic polymer may be polyaniline or polythiophene and a derivative of these materials, and the acrylic polymer as the binder may be polyacrylic acid and a derivative of these materials (As an aspect 2). Furthermore, the metal particles are preferably those of nickel, a nickel alloy, or silver (As an aspect 3).

Furthermore, the organic polymer as the binder may be a cross-linked polymer elastomer including a cross-link formed by peroxide cross-linking or ultraviolet cross-linking (As an aspect 4).

An electromagnetic-wave shield according to the present invention is composed of a conductive polymer elastomer composition having a three-dimensional mesh structure formed of a conductive organic polymer that covers a large number of conductive metal particles and that cross-links the metal particles, the conductive polymer elastomer composition including a non-conductive organic polymer composed of an acrylic polymer that is immiscible with the conductive organic polymer that maintains the three-dimensional mesh structure formed of the conductive particle complex of the metal particles and the conductive organic polymer, the conductive polymer elastomer composition is formed in the shape of a film or a sheet, and the electromagnetic-wave shield preferably has shielding characteristics with an attenuation factor of not less than 30 dB at 100 MHz (As an aspect 5).

Furthermore, in order to prevent oxygen from absorbing radicals generated by cross-linking thereby inhibiting the reaction, preferably, the conductive polymer elastomer composition is held between heat-resistant polymer films so that the organic polymer serving as the binder is coated so as to prevent from being exposed to oxygen (As an aspect 6).

### EFFECT OF THE INVENTION

By using the conductive polymer elastomer composition having the three-dimensional mesh structure according to the present invention as an electromagnetic-wave shield material or the like, it is possible to simultaneously achieve high light transmissivity and electromagnetic-wave shielding.

Furthermore, regarding “blackening” (black-shadowing for emphasizing other colors), which is often needed for display materials, the function of blackening was achieved by the mesh-shaped polymer organic conductor having light-absorbing characteristics in the visible spectrum.

### BRIEF DESCRIPTION OF THE DRAWINGS

FIG. 1 is a sectional view of a conductive polymer elastomer composition according to the present invention;

FIG. 2 is a perspective view illustrating a three-dimensional mesh structure of the conductive polymer elastomer composition according to the present invention;

FIG. 3 is a schematic diagram illustrating a process of manufacturing an electromagnetic-wave shield according to the present invention; and

FIG. 4 is a schematic diagram illustrating a process of coating with heat-resistant films.

### EXPLANATION OF THE REFERENCE NUMERALS

10: Conductive polymer elastomer composition
11: Conductive metal particles
12: Conductive organic polymer
13: Non-conductive organic polymer as binder
14: Heat-resistant film
20: Glass plate
21: Bar coater
22: Ultraviolet lamp

### PREFERRED EMBODIMENT OF THE INVENTION

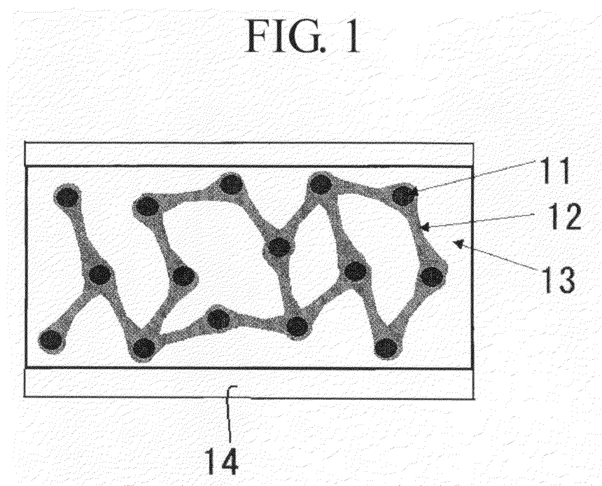

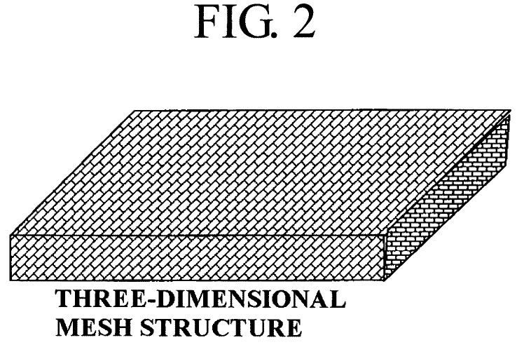

A conductive polymer elastomer composition 10, having an overall configuration shown in FIG. 1, is herein formed in the shape of a sheet, includes a conductive organic polymer 12, as a conductive particle complex, that covers a large number of conductive metal particles 11 and that cross-links the large number of conductive metal particles to form a three-dimensional mesh structure, and includes a non-conductive organic polymer 13 as a binder. The non-conductive organic polymer 13 maintains isolation from the conductive organic polymer 12 and is composed of an acrylic polymer for maintaining the three-dimensional mesh structure formed of the conductive particle complex of the metal particles and the conductive organic polymer 12, the acrylic polymer having an SP value different from that of the conductive organic polymer 12, with a difference not less than 1 in SP value, and being immiscible with the conductive organic polymer 12.

In the same figure, 14 denotes heat-resistant films provided as coatings on both surfaces of the conductive polymer elastomer composition.

### 1. Conductive Polymer Elastomer Composition

[1] Conductive Organic Polymer
Conjugated polymers, such as the following, can be used:
Polyacetylene-based polymers,
Polyphenylene-based polymers,
Heterocyclic polymers,
Ionic polymers (ionic polymeric high molecule).

Examples of polyacetylene-based polymers include polyacetylene and polyphenylacetylene.

Examples of polyphenylene-based polymers include polyparaphenylene and polyphenylenevinylene.

Examples of heterocyclic polymers include polypyrrole and polythiophene.

Examples of ionic polymers include polyaniline.

Among these, from the viewpoint of adhesion with metal particles, heterocyclic polymers and ionic polymers are preferred.

[2] Metal Particles

Metal particles having conductivity can be used. For example, chromium, iron, cobalt, nickel, zinc, tin, gold, silver, aluminum, and alloys of two or more of these metals can be used.

Among these, from the viewpoint of conductivity, nickel, aluminum, silver, gold, and alloys of these metals are preferred.

A metal part of the conductor is preferably nickel, a nickel alloy, or silver, among elements having standard electrode potentials not higher than −0.25 V.

[3] Organic Polymer as Binder

Acrylic polymers are used; herein, polyacrylic acids, such as butyl acrylate, ethyl acrylate, and methyl acrylate, and polyacrylic acid esters, which are derivatives of polyacrylic acids, are used.

[4] Solvents

The following solvents can be used as needed for an electromagnetic-wave shield material according to the present invention.

As solvents, aliphatic hydrocarbons, aromatic hydrocarbons, alcohol, ketones, esters, ethers, halogenized hydrocarbons, and mixtures of these materials can be used.

Examples of aliphatic hydrocarbons include hexane, octane, and paraffin oil.

Examples of aromatic hydrocarbons include benzene, toluene, and xylene.

Examples of alcohol include methanol, isopropyl alcohol, and buthanol.

Examples of ketones include acetone, methyl ethyl ketone, and methyl isobutyl ketone.

Examples of esters include ethyl acetate, butyl acetate, and methyl propionate.

Examples of ethers include diethyl ether, dibutyl ether, and tetrahydrofuran.

Examples of halogenized hydrocarbons include chloroform, methylene dichloride, and ethylene dichloride.

[5] Electromagnetic-Wave Shield

An electromagnetic-wave shield can be obtained by grounding the conductive polymer elastomer composition obtained through [1] to [4], for example, by forming a connection to the conductive organic polymer via a solderless terminal.

2. The overall manufacturing process, including formation of the electromagnetic-wave shield, may include the steps of:

[1] formation of a conductive particle complex of conductive metal particles and a conductive organic polymer, [2] mixing of the conductive particle complex and a binder resin, [3] formation into a sheet shape having electromagnetic-wave shielding characteristics, and optionally a step of coating both surfaces of the conductive polymer elastomer composition with heat-resistant films.

### EMBODIMENTS

Hereinafter, individual manufacturing steps will be described in detail.

[1] Preparation of Conductor and [2] Conductive Particle Complex of Conductor and Conductive Organic Polymer

As a complex of metal powder and a conductive organic polymer material, the following method (precipitation polymerization) was used.

In a 3000-cc beaker, while mechanically dispersing 100 grams of nickel metal particles in 2000 cc of isopropyl alcohol as a solvent, the surfaces of the metal particles were covered with the following conductive organic polymers by methods described below to obtain conductive particle complexes.

### a) Case Where Polyaniline was Used as a Polymer

Method 1

By using 100 g of aniline as an active agent, stirring was performed for two hours at 25° C. in the presence of 0.5 grams of ammonium persulfate, whereby 150 grams of polyaniline-covered nickel particles were obtained.

Method 2

6.8 grams of ferric chloride (hexahydrate) was dissolved as an active agent in 3000 ml of aqueous methanol solution and the temperature was maintained at 0° C. While stirring the mixture, 2 ml of aniline was slowly added dropwise (dropping period of one hour), and the reaction was allowed to proceed for six hours in the presence of formic acid.

The reaction mixture was adjusted to pH 10 with aqueous ammonia solution (25%), and then reprecipitation and filtration were performed using isopropyl alcohol.

130 grams of conductive particle complex composed of polyaniline-covered nickel particles was obtained.

### b) Case Where Polypyrrole was Used as a Polymer

Method 1

100 grams of pyrolle was stirred for two hours at 25° C. in the presence of 0.5 grams of ammonium persulfate, whereby about 80 grams of conductive particle complex composed of polypyrrole-covered nickel particles was obtained.

Method 2

6.8 grams of ferric chloride (hexahydrate) was dissolved in 3000 ml of aqueous methanol solution and the temperature was maintained at 70° C. While stirring the mixture, 2 ml of pyrrole was slowly added dropwise (dropping period of one hour), and the reaction was allowed to proceed for six hours in the presence of formic acid.

The reaction mixture was adjusted to pH 10 with aqueous ammonia solution (25%) and then reprecipitation and filtration were performed using isopropyl alcohol.

About 105 grams of conductive particle complex composed of polypyrrole-covered nickel particles was obtained.

c) Case Where Polythiophene was Used as a Polymer

Method 1

100 grams of thiophene was stirred for two hours at 25° C. in the presence of 0.5 grams of ammonium persulfate, whereby 50 grams of conductive particle complex composed of polythiophene-covered nickel particles was obtained.

Method 2

6.8 grams of ferric chloride (hexahydrate) was dissolved in 3000 ml of aqueous methanol solution and the temperature was maintained at 70° C. While stirring the mixture, 2 ml of thiophene was slowly added dropwise (dropping period of one hour), and the reaction was allowed to proceed for six hours in the presence of formic acid. The reaction mixture was adjusted to pH 10 with aqueous ammonia solution (25%), and then reprecipitation and filtration were performed using isopropyl alcohol. 85 grams of polythiophene-covered nickel particles was obtained.

The following shows details of the above materials, together with binders to be described later.

TABLE 1

| | | | |
|---|---|---|---|
| Material name | Manufacturer | Product name | Product number |

Metal particles

| | | | |
|---|---|---|---|
| Nickel | Fukuda Metal Foil & | Nickel powder carbonyl | #255 |
| | Powder Co., Ltd | nickel | |
| Same as above | Same as above | Same as above | #123 |
| Same as above | Same as above | Same as above | #234 |
| Same as above | Same as above | Atomized nickel | #350 |
| Same as above | Same as above | Same as above | #250 |

Solvent

| | | | |
|---|---|---|---|
| Isopropyl alcohol | Wako Pure Chemical | 2-propanol | Same as left |
| | Industries, Ltd. | | |

Conductive organic polymer

| | | | |
|---|---|---|---|
| Aniline | Wako Pure Chemical | Aniline | Same as left |
| | Industries, Ltd. | | |
| Pyrrole | Same as above | Pyrrole | Same as left |
| Thiophene | Same as above | Thiophene | Same as left |

Non-conductive polymer as binder

| | | | |
|---|---|---|---|
| Butyl acrylate | Nippon Shokubai Co., Ltd. | Butyl acrylate | Same as left |
| Ethyl acrylate | Same as above | Ethyl acrylate | Same as left |
| Methyl acrylate | Same as above | Methyl acrylate | Same as left |

Active agent

| | | | |
|---|---|---|---|
| Ammonium persulfate | Wako Pure Chemical | Ammonium persulfate | Same as left |
| | Industries, Ltd. | | |
| Methanol | Same as above | Methanol | Same as left |
| Formic acid | Same as above | Formic acid | Same as left |

Photopolymerization initiator

| | | |
|---|---|---|
| Irgacure 184 | Ciba Specialty Chemicals | Irgacure 184 |
| | Corporation | |

For the electromagnetic-wave shield material according to the present invention, the above-described solvents, including isopropyl alcohol, can be used as needed.

Mixing and Dispersion

For the purpose of mixing and dispersion for obtaining a three-dimensional mesh structure according to the present invention, a three roll mill, a bead mill, a dispermill, a high-pressure homogenizer, a kneader, a planetary mixer, or the like can be used.

The temperature for mixing and dispersion is usually in a range of 5° C. to 100° C., and the period of mixing and dispersion is usually in a range of 5 minutes to 10 hours.

As is generally known, a polymer has a specific solubility in a solvent.

The solubility parameter is a known index of solubility in a solvent.

The solubility parameter (δ, SP value) is explained as follows.

Since it is assumed that intermolecular forces are the only forces that act between the solvent and the solute, the solubility parameter is used as an index that represents the intermolecular forces, and it is empirically known that the solubility increases as the difference between the SP values of two components becomes smaller.

The regular solution theory is based on a model in which the intermolecular forces are the only forces acting between the solvent and the solute, so that it is possible to assume that the only interaction that causes cohesion of liquid molecules is the intermolecular forces.

Since the cohesive energy of liquid is equivalent to vaporization enthalpy, from the molar heat ΔH of vaporization and the molar volume V, the solubility parameter is defined as:

δ=\sqrt{ΔH/V−RT} Eq. 1

That is, the solubility parameter (cal/cm³)^{1/2} is calculated from the square root of the vaporization heat needed for vaporization of one molar volume of liquid.

It is rare that an actual solution is a regular solution, and forces other than intermolecular forces, such as hydrogen bonds, also act between the solvent and the solute. Thus, whether two components are mixed or separated from each other is determined thermodynamically according to the difference between the mixing enthalpy and mixing entropy of the components.

Empirically, however, materials with similar solubility parameters tend to mix easily.

Therefore, the SP values serve as an index for determining the ease of mixing between the solvent and the solute, so that according to the present invention, a solvent and a solute with dissimilar values are chosen.

The SP values (theoretical values) of typical solvents and typical polymers that serve as binders and conductive polymers are shown below.

TABLE 2
SP values (theoretical values) of typical polymers that serve as solvents, binders,
and conductive polymers

| | SP | | SP | | SP |
|---|---|---|---|---|---|
| Solvent | value | Binder | value | Conductive polymer | value |
| Hexane | 7.3 | Polytetrafluoroethylene | 6.2 | Polypyrrole | 8.9 |
| Butyl acetate | 8.5 | Butyl rubber | 7.3 | Polyaniline | 11.5 |
| Xylene | 8.8 | Polyethylene | 7.9 | Polythiophene | 12.5 |
| Toluene | 8.8 | Polyisoprene | 7.9-8.3 | Polyacetylene | |
| Ethyl acetate | 9 | Styrene-butadiene rubber | 8.1-8.5 | Polyphenylacetylene | |
| Benzene | 9.2 | Polystyrene | 8.6-9.7 | Polyparaphenylene | |
| Dibutyl phthalate | 9.4 | Chloroprene | 9.2 | Polyphenylenevinylene | |
| Acetone | 10 | Polymethacrylate | 9.2 | | |
| Isopropanol | 11.5 | Vinyl acetate | 9.4 | | |
| Acetonitrile | 11.9 | Chloroethylene | 9.5-9.7 | | |
| Dimethylformamide | 12 | Epoxy resin | 9.7-10.9 | | |
| Acetic acid | 12.6 | Nitrocellulose | 10.1 | | |
| Ethanol | 12.7 | Polyethylene terephthalate | 10.7 | | |
| Cresol | 13.3 | Polymethacrylate resin | 10.7 | | |
| Formic acid | 13.5 | Cellulose diacetate | 11.4 | | |
| Ethylene glycol | 14.2 | Acrylic ester polymer | 9-10.5 | | |
| Phenol | 14.5 | | | | |
| Methanol | 14.5-14.8 | | | | |
| Octane | | | | | |
| Isopropyl alchohol | 11.5 | | | | |
| Buthanol | 11.4 | | | | |

In Table 2, polymethacrylate resin and acrylic ester polymer are acrylic polymers.

Thus, when acrylic ester polymer is used as the binder, polypyrrole has a similar SP value, whereas polyaniline and polythiophene have dissimilar SP values.

Polymers with similar SP values tend to dissolve (referred to as miscible), whereas polymers with dissimilar SP values do not dissolve (immiscible). In order to obtain a three-dimensional mesh structure according to the present invention and maintain isolation between the conductive organic polymer and the non-conductive polymer as a binder for maintaining the three-dimensional mesh structure, the mutually immiscible latter combination is used. The solvent is preferably miscible with the non-conductive polymer as the binder, so that a solvent with a similar SP value is used.

Coating Method

As a step of coating the conductive metal particles with the conductive organic polymer, known coating methods can be used as methods for forming films to cover the conductive metal particles.

For example, a solvent coating method or a powder coating method can be used. The solvent coating method refers to a method of coating the surfaces of the metal particles with a resin dissolved in a solvent by using an air spray or the like and then vaporizing the solvent, whereby the surfaces of the metal particles are covered. On the other hand, the powder coating method refers to a method of covering the surfaces of the metal particles with resin microparticle powder by using an air spray or the like and then raising the temperature to melt the resin powder, thereby achieve coating.

[3] Mixing of Complex and Binder Resin and [4] Manufacturing of Sheet

The conductive particle complex thus obtained was mixed with resin composed of non-conductive organic polymers as binders.

As the binder that is mixed, a polymer that is in the liquid phase at room temperature is desired.

The non-conductive organic polymers used as the binders were:

acrylic acid esters including butyl acrylate, ethyl acrylate, and methyl acrylate.

[Case of Ultraviolet Radiation Curing]

200 grams of the composition thus obtained was put into a 3000-cc beaker, 1000 grams of butyl acrylate was added, 0.1 grams of Irgacure 184 was added as a photopolymerization initiator, and then the mixture was stirred for three hours.

[Case of Infrared Heat Curing]

200 grams of the conductive polymer material complex was put into a 3000-cc beaker, 1000 grams of butyl acrylate was added, 2.0 grams of Peroyl TCP was added as a peroxide curing agent, and then the mixture was stirred for one hour.

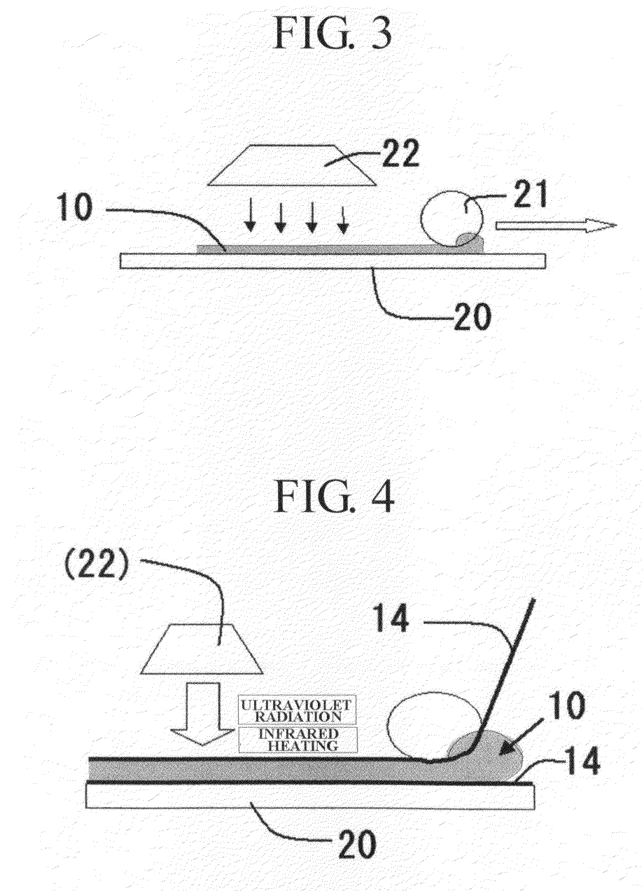

As shown in FIG. 3, the mixture was released onto a glass plate 20 through fluoro release treatment, and then the mixture was applied with a thickness of 0.8 mm using a bar coater 21.

An ultraviolet lamp 22 (manufacturer, Ushio Inc., product name UM452) performed radiation for 0.3 minutes at a distance of 15 mm to the target, thereby forming double bonds by cross-linking.

A sheet-shaped electromagnetic-wave shield with a thickness of 0.5 mm was obtained.

As shown in FIG. 1, both surfaces of the electromagnetic-wave shield composed of the conductive polymer elastomer composition can be coated with the heat-resistive films 14.

[Film Forming Methods]

As shown in FIG. 4, a 100-μm polyester film (Toray, Lumirror S10 #400) was placed on the glass plate 20, and then the conductive polymer elastomer composition was applied to a thickness of 0.8 mm.

At the time of application, as heat-resistant films, polyester films 14 (Toray, Lumirror S10 #100) with a thickness of 25 μm were held on the application surface of the conductive polymer elastomer composition so that the configuration becomes: film 14/conductive polymer elastomer composition 10/film 14.

As the films 14 used, polymers having softening temperatures not lower than 60° C. are suitable.

For example, polyethylene terephthalate, polyarylate, polycarbonate, liquid crystal polymer, polyamide-imide, or polyetheretherketone can be used (see Table 3).

TABLE 3

| Resin acronym | Generic resin name | Product name |
|---|---|---|
| PC | Polycarbonate | Panlite |
| Modified PPE | Modified polyphenylene ether | Noryl |
| PBT | Polybutylene terephthalate | Duranex |
| PPS | Polyphenylene sulfide | Susteel |
| PPS | Polyphenylene sulfide | Torelina |
| PSU | Polysulfone | Udel |
| PES | Polyethersulfone | Radel A |
| PEEK | Polyetheretherketone | |
| | Polysulfone | |
| | Polyethersulfone | |
| PAR | Polyarylate | U polymer |
| LCP | Liquid crystal polymer | Sumika super |
| LCP | Liquid crystal polymer | DIC LCP |
| LCP | Liquid crystal polymer | Siveras |
| LCP | Liquid crystal polymer | Zenite |
| LCP | Liquid crystal polymer | Vectra |
| LCP | Liquid crystal polymer | Novaccurate |
| LCP | Liquid crystal polymer | Rodrun |
| LCP | Liquid crystal polymer | Idemitsu LCP |
| PAI | Polyamide-imide | TI polymer |
| PI | Polyimide | Kapton |
| PI | Polyimide | Upilex |
| PBI | Polybenzimidazole | Celazole |

Evaluation Method

Regarding compositions T1 to T23 in Tables 4 to 6, evaluation was performed using samples of 150×150 mm.

Electromagnetic-wave shielding characteristics

Electromagnetic-wave shielding characteristics were measured by the “KEC method” described below.

The KEC method is a method of measuring electromagnetic-wave shielding characteristics, developed and devised at the “KEC (Kansai Electronic Industry Development Center)”.

With the method of measuring the electromagnetic-wave shielding effect, developed at KEC, it is relatively easy to measure and evaluate the electromagnetic-wave shielding effect in the case of a sheet-shaped material.

There exist two types of known measurement devices, not shown, i.e., devices for evaluating the electric-field shielding effect and evaluating the magnetic-field shielding effect.

The device for evaluating electric-field shielding adopts the dimensional proportions of TEM cells, and has a structure divided in left-right symmetry in a plane perpendicular to the direction of the transmission axis thereof. However, in order to prevent formation of a short circuit by insertion of a measurement sample, the length of the center conductor is shorter by 2 mm compared with the cutting surface.

Measurement of Total Light Transmission

Measurement was performed by the method of testing the total light transmission of plastic transparent materials (JISK 7361, ISO 13468) and the method of optical testing of plastics (JIS K 7105, ASTM D 1003).

Measurement of Volume Specific Resistance Value

Measurement was performed according to the standard (JIS K7194) regarding the four-probe method of testing the resistivity of conductive plastics.

Hardness

Hardness was represented in terms of “Asuka C” hardness conforming to JIS K7312.

Anti-Corrosion Test

A sample of 30 mm×30 mm was put in a 500-ml beaker containing 400 ml of water, and the change in resistance after the content was left for 24 hours at room temperature was observed.

| | | |
|---|---|---|
| * | Rate of change | Not more than 10% |
| ** | Rate of change | 10% to 30% |
| *** | Rate of change | Not less than 30% |

Tables 4 to 6 show the results of the above measurements regarding hardness, volume specific resistance value, light transmittance, anti-corrosion, and the results of measurements for testing the shielding characteristics.

TABLE 4

| | | | |
|---|---|---|---|
| | | Generic chemical | Particle diameter |
| Composition | Manufacturer | name | (μm) |

Binder polymer

| | | | |
|---|---|---|---|
| 1 | Butyl acrylate | Nippon Shokubai Co., Ltd | Acrylic ester |
| 2 | Ethyl acrylate | Nippon Shokubai Co., Ltd | Acrylic ester |
| 3 | 2-ethyl-hexyl | Nippon Shokubai Co., Ltd. | Acrylic ester |
| | acrylate | | |
| 4 | Acrylic acid | Mitsubishi Rayon Co., Ltd | Acrylic acid |
| 5 | Methyl | Mitsubishi Rayon Co., Ltd | Methyl |
| | methacrylate | | methacrylate |

Organic conductor

| | | | |
|---|---|---|---|
| 6 | Polyaniline | (Own) | Polyaniline |
| 7 | Polypyrrole | (Own) | Polypyrrole |
| 8 | Polythiophene | (Own) | Polythiophene |
| 9 | Polyisothianaphthene | (Own) | Polyisothianaphthene |
| 10 | Polyethylene- | (Own) | Polyethylene- |
| | dioxythiophene | | dioxythiophene |

Metal particles
Nickel

| | | | | |
|---|---|---|---|---|
| 11 | Carbonyl | Fukuda Metal Foil & Powder | Metal powder | 5 |
| | nickel #255 | Co., Ltd. | | |
| 12 | Carbonyl | Fukuda Metal Foil & Powder | Metal powder | 15 |
| | nickel #123 | Co., Ltd. | | |
| 13 | Carbonyl | Fukuda Metal Foil & Powder | Metal powder | 20 |
| | nickel #234 | Co., Ltd. | | |
| 14 | Atomized | Fukuda Metal Foil & Powder | Metal powder | 40 |
| | nickel #325 | Co., Ltd. | | |
| 15 | Atomized | Fukuda Metal Foil & Powder | Metal powder | 80 |
| | nickel #250 | Co., Ltd. | | |

Nickel-based alloy

| | | | | |
|---|---|---|---|---|
| 16 | Cupronickel | Fukuda Metal Foil & Powder | Metal powder | 30 |
| | #325 | Co., Ltd. | | |
| 17 | Nickel silver | Fukuda Metal Foil & Powder | Metal powder | 30 |
| | #325 | Co., Ltd. | | |

Silver powder

| | | | | |
|---|---|---|---|---|
| 18 | AgC74SE | Fukuda Metal Foil & Powder | Metal powder | 15 |
| | | Co., Ltd. | | |
| 19 | AgC132 | Fukuda Metal Foil & Powder | Metal powder | 10 |
| | | Co., Ltd. | | |
| 20 | AgC-E | Fukuda Metal Foil & Powder | Metal powder | 30 |
| | | Co., Ltd. | | |
| 21 | AgC-GS | Fukuda Metal Foil & Powder | Metal powder | 20 |
| | | Co., Ltd. | | |

Copper powder

| | | | | |
|---|---|---|---|---|
| 22 | FCC155 | Fukuda Metal Foil & Powder | Metal powder | 15 |
| | | Co., Ltd. | | |
| 23 | CE25 | Fukuda Metal Foil & Powder | Metal powder | 20 |
| | | Co., Ltd. | | |
| 24 | CE20 | Fukuda Metal Foil & Powder | Metal powder | 10 |
| | | Co., Ltd. | | |

Tin

| | | | | |
|---|---|---|---|---|
| 25 | Sn100 | Fukuda Metal Foil & Powder | Metal powder | 80 |
| | | Co., Ltd. | | |

| | | | | | Target |
|---|---|---|---|---|---|
| Characteristics | | | | Unit | value |
| A | Hardness | | | Asuka C | Not more |
| | | | | | than 80 |
| B | Volume specific | Measurement | SRIS 2301 | Ω · cm | Not more |
| | resistance value | | | | than 0.1 |
| C | Light transmittance | Measurement | Spectrophotometer | % | Not less |
| | | | | | than 80 |
| D | Anti-corrosion | | | | * or ** |
| E | Shielding performance | | | dB | Not less |
| | (Attenuation factor at 100 MHz) | | | | than 30 |

TABLE 5

| | | | | | | | | | | | |
|---|---|---|---|---|---|---|---|---|---|---|---|
| Composition | T1 | T2 | T3 | T4 | T5 | T6 | T7 | T8 | T9 | T10 | T11 |

Binder polymer

| | | | | | | | | | | | |
|---|---|---|---|---|---|---|---|---|---|---|---|
| 1 | * | * | * | * | * | * | * | * | * | * | * |
| 2 | | | | | | | | | | | |
| 3 | | | | | | | | | | | |
| 4 | | | | | | | | | | | |
| 5 | | | | | | | | | | | |

Organic conductor

| | | | | | | | | | | | |
|---|---|---|---|---|---|---|---|---|---|---|---|
| 6 | * | * | * | * | * | * | * | * | * | * | * |
| 7 | | | | | | | | | | | |
| 8 | | | | | | | | | | | |
| 9 | | | | | | | | | | | |
| 10 | | | | | | | | | | | |

Metal particles

| | | | | | | | | | | | |
|---|---|---|---|---|---|---|---|---|---|---|---|
| 11 | * | | | | | | | | | | |
| 12 | | * | | | | | | | | | |
| 13 | | | * | | | | | | | | |
| 14 | | | | * | | | | | | | |
| 15 | | | | | * | | | | | | |
| 16 | | | | | | * | | | | | |
| 17 | | | | | | | * | | | | |
| 18 | | | | | | | | * | | | |
| 19 | | | | | | | | | * | | |
| 20 | | | | | | | | | | * | |
| 21 | | | | | | | | | | | * |
| 22 | | | | | | | | | | | |
| 23 | | | | | | | | | | | |
| 24 | | | | | | | | | | | |

Characteristics

| | | | | | | | | | | | |
|---|---|---|---|---|---|---|---|---|---|---|---|
| A | 70 | 65 | 65 | 63 | 55 | 70 | 68 | 69 | 74 | 65 | 50 |
| B | 0.01 | 0.04 | 0.03 | 0.06 | 0.08 | 0.09 | 0.09 | 0.001 | 0.002 | 0.006 | 0.007 |
| C | 90 | 88 | 88 | 87 | 89 | 88 | 88 | 85 | 85 | 84 | 83 |
| D | * | * | * | * | * | ** | ** | ** | ** | ** | * |
| E | 48 | 45 | 45 | 44 | 43 | 42 | 39 | 51 | 50 | 50 | 49 |

TABLE 6

| | | | | | | | | | | | | |
|---|---|---|---|---|---|---|---|---|---|---|---|---|
| Composition | T12 | T13 | T14 | T15 | T16 | T17 | T18 | T19 | T20 | T21 | T22 | T23 |

Binder polymer

| | | | | | | | | | |
|---|---|---|---|---|---|---|---|---|---|
| 1 | * | * | * | * | | | | | * |
| 2 | | | | | * | | | | |
| 3 | | | | | | * | | | |
| 4 | | | | | | | * | | |
| 5 | | | | | | | | * | |

Organic conductor

| | | | | | | | | | | | | |
|---|---|---|---|---|---|---|---|---|---|---|---|---|
| 6 | * | * | * | * | * | * | * | * | | | | |
| 7 | | | | | | | | | | * | | |
| 8 | | | | | | | | | * | | | |
| 9 | | | | | | | | | | | * | |
| 10 | | | | | | | | | | | | * |

Metal particles

| | | | | | | | | | |
|---|---|---|---|---|---|---|---|---|---|
| 11 | | | | | * | * | * | * | * |
| 12 | | | | | | | | | |
| 13 | | | | | | | | | |
| 14 | | | | | | | | | |
| 15 | | | | | | | | | |
| 16 | | | | | | | | | |
| 17 | | | | | | | | | |
| 18 | | | | | | | | | |
| 19 | | | | | | | | | |
| 20 | | | | | | | | | |
| 21 | | | | | | | | | |
| 22 | * | | | | | | | | |
| 23 | | * | | | | | | | |
| 24 | | | * | | | | | | |
| | | | | * | | | | | |

Characteristics

| | | | | | | | | | | | | |
|---|---|---|---|---|---|---|---|---|---|---|---|---|
| A | 75 | 69 | 70 | 55 | 70 | 75 | 77 | 79 | 70 | 70 | 70 | 70 |
| B | 0.08 | 0.09 | 0.1 | 0.5 | 0.01 | 0.04 | 0.06 | 0.08 | 0.01 | 1000 | 0.01 | 0.01 |
| C | 79 | 78 | 79 | 85 | 90 | 90 | 90 | 90 | 88 | 88 | 88 | 88 |
| D | *** | *** | *** | *** | * | * | * | * | * | * | * | * |
| E | 43 | 39 | 29 | 25 | 48 | 45 | 44 | 43 | 47 | 0 | 47 | 47 |

### INDUSTRIAL APPLICABILITY

A conductive polymer elastomer composition according to the present invention can be used as a packing material of an anti-static bag or a packing material for an electronic device, and can also be used as an electromagnetic-wave shield for protecting electronic devices from electromagnetic interference and taking anti-noise measures or the like to prevent improper operation or the like of electronic devices.

1.-6. (canceled)

7. A conductive polymer elastomer composition that is a transparent elastomer provided in the immediate vicinity of a viewer's side of a display unit, said conductive polymer elastomer composition comprising:
conductive and non-conductive organic polymers and conductive metal particles, the organic polymers having a non-conductive acrylic polymer as a binder and a three-dimensional mesh structure formed of a conjugated conductive organic polymer including a double bond in its repeating unit.

8. A conductive polymer elastomer composition according to claim 7, wherein the conductive organic polymer is polyaniline or polythiophene and a derivative of these materials, and the acrylic polymer as the binder is polyacrylic acid and a derivative of these materials.

9. A conductive elastomer composition according to claim 7, wherein the metal particles are those of nickel, a nickel alloy, or silver.

10. A conductive polymer elastomer composition according to claim 7, wherein the organic polymer serving as the binder is a cross-linked polymer elastomer including a cross-linked polymer formed by peroxide cross-linking or ultraviolet cross-linking.

11. A conductive polymer elastomer composition according to claim 8, wherein the organic polymer serving as the binder is a cross-linked polymer elastomer including a cross-linked polymer formed by peroxide cross-linking or ultraviolet cross-linking.

12. An electromagnetic-wave shield, comprising:
a conductive polymer elastomer composition having a three-dimensional mesh structure formed of a conductive organic polymer that covers a large number of conductive metal particles and that cross-links the metal particles;
the conductive polymer elastomer composition includes a non-conductive organic polymer composed of an acrylic polymer that is immiscible with the conductive organic polymer and that maintains the three-dimensional mesh structure formed of the conductive particle complex of the metal particles and the conductive organic polymer; and
the conductive polymer elastomer composition is formed in the shape of a film or a sheet.

13. An electromagnetic-wave shield according to claim 12, wherein the film- or sheet-shaped conductive polymer elastomer composition is held between heat-resistant polymer films so that the organic polymer serving as the binder is coated so as to prevent from being exposed to oxygen.
